(19) United States
(12) Patent Application Publication
(10) Pub. No.: US 2026/0354128 A1
(43) Pub. Date: Nov. 5, 2026

(54) METHOD OF MANUFACTURING A SEMICONDUCTOR DEVICE

(71) Applicant: Taiwan Semiconductor Manufacturing Company, Ltd., Hsinchu (TW)

(72) Inventors: Yen-Yu KUO, Hsinchu (TW); Yu-Chung SU, Hsinchu (TW); Yahru CHENG, Hsinchu (TW)

(73) Assignee: Taiwan Semiconductor Manufacturing Company, Ltd., Hsinchu (TW)

(21) Appl. No.: 19/183,039

(22) Filed: Apr. 18, 2025

(51) Int. Cl. H01L 21/027; G03F 7/004; G03F 7/11; G03F 7/16; G03F 7/20; H01L 21/311; H01L 21/3213

(52) U.S. Cl. CPC H10P 76/2043; G03F 7/0042; G03F 7/11; G03F 7/168; G03F 7/2041; H10P 50/71; H10P 50/73; H10P 76/2042

(57) ABSTRACT

The present disclosure relates to photolithography processing and photolithographic materials. The present disclosure provides a method of manufacturing a semiconductor device through immersion photolithography. The metallic photoresist includes a floating additive material to protect the metallic photoresist from being dissolved by the immersion fluid of the immersion photolithography apparatus during actinic radiation exposure.

### BACKGROUND

As the semiconductor industry has progressed into nanometer technology process nodes in pursuit of higher device density, higher performance, and lower costs, challenges from both fabrication and design issues have resulted in the development of devices with smaller critical dimensions. The photolithography operation is crucial to reducing the critical dimension. Immersion lithography has been developed to provide high-speed patterning of features having reduced critical dimensions. Multiple photolithographic exposures are provided over the same portion of a semiconductor wafer to form multiple patterned layers of semiconductor devices.

Photolithographic materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other, or vice versa.

As the size of individual devices has decreased, process windows for photolithographic processing have become tighter and tighter. As such, advances in the field of photolithographic processing are necessary to maintain the ability to scale down the devices, and further improvements are needed in order to meet the desired design criteria such that the march towards smaller and smaller components may be maintained.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a deposition apparatus according to some embodiments of the present disclosure.

FIG. 2 illustrates a process flow of manufacturing a semiconductor device according to some embodiments of the present disclosure.

FIGS. 3A-3F show process stages of sequential operations according to some embodiments of the present disclosure.

FIG. 4 is a schematic illustration of an immersion photolithography apparatus according to some embodiments of the present disclosure.

FIGS. 5A-5C show process stages of sequential operations according to some embodiments of the present disclosure.

FIGS. 6A-6C shows examples of metallic cores according to some embodiments of the present disclosure.

FIG. 6D shows examples of floating additives according to some embodiments of the present disclosure.

FIG. 7 shows a flowchart of a method of manufacturing a semiconductor device according to some embodiments of the present disclosure.

FIG. 8 shows a flowchart of a method of manufacturing a semiconductor device according to some embodiments of the present disclosure.

FIG. 9 shows a flowchart of a method of forming a photoresist pattern, according to some embodiments of the present disclosure.

FIG. 10A and FIG. 10B are diagrams of a controller according to some embodiments of the present disclosure.

### DETAILED DESCRIPTION

It is to be understood that the following disclosure provides many different embodiments, or examples, for implementing different features of the present application. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity. In the accompanied drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in/between the described operations, and the order of operations may be changed. In the present disclosure, a phrase “one of A, B and C” means “A, B and/or C” (A, B, C, A and B, A and C, B and C, or A, B, and C), and does not mean one element from A, one element from B and one element from C, unless otherwise described. Materials, configurations, dimensions, processes, and/or operations same as or similar to those described with one embodiment may be employed in the other embodiments and the detailed explanation may be omitted.

Immersion lithography has been implemented to take advantage of the processing technology's capability for improved resolution. Immersion lithography features the use of a liquid medium to fill the entire gap between the last objective lens element of the light projection system and the semiconductor wafer (substrate) surface during the light exposure operations of the photoresist pattern printing process. In some instances, the immersion lithography process utilizes an argon fluoride (ArF) excimer laser at a wavelength of 193 nm. The liquid medium used as the immersion lens provides an improved index of refraction for the exposing light, thus improving the resolution capability of the lithographic system. This is represented by the Rayleigh Resolution formula, R=k₁λ/N.A., where R (feature size resolution) is dependent upon k₁ (certain process constants), λ (wavelength of the transmitted light), and the N.A. (numerical aperture of the light projection system). It is noted that N.A. is also a function of the index of refraction where N.A.=n sin θ. Variable n is the index of refraction of the liquid medium between the objective lens and the wafer substrate, and θ is the acceptance angle of the lens for a transmitted light.

As the index of refraction (n) becomes higher for a fixed acceptance angle, the numerical aperture (N.A.) of the projection system becomes larger thus providing a lower R value, i.e., a higher resolution. In some embodiments, the immersion lithographic system uses de-ionized water as the immersion fluid between an objective lens and the wafer substrate. At one of the wavelengths, for example 193 nm, de-ionized water at 20 °C has an index of refraction of approximately 1.44 versus air, which has an index of refraction at approximately 1.00. Thus, immersion lithographic systems offer a significant improvement to the resolution of the photolithography processes.

Improving processing critical dimension stability, improving the line width roughness (LWR), and reducing the critical dimension variation are desirable in the field of immersion photolithographic processing to continue scaling down the devices and efficiently increase semiconductor device yield. ArF immersion photolithography allows for the fabrication of finer details and is capable of achieving a resolution of a line and space below 40 nm. As discussed above, the introduction of a liquid medium between the lens and the wafer, ArF immersion lithography effectively increases the numerical aperture, allowing for improved focus and resolution. ArF immersion lithography facilitates the creation of high-density, multi-functional chips.

Metallic photoresists have been used in ArF immersion photolithography for higher etching selectivity, improved LWR, and higher photon absorption. It has been found that certain metals have higher photon absorption than organic photoresists that include C, N, and O atoms in the polymers of the organic photoresists. However, during ArF immersion processing, metallic photoresists are susceptible to dissolving by the liquid medium which can lead to decreased lithographic performance and decreased semiconductor device yield.

In embodiments of the present disclosure, the ArF immersion lithographic performance is further improved by treating the metallic photoresist layer with a floating additive composition that floats over the photoresist layer during actinic radiation exposure and protects the metallic resist from being dissolved by the liquid medium during the development operation. The floating additive composition may be applied to the metallic photoresist layer at various times during the photolithographic patterning process.

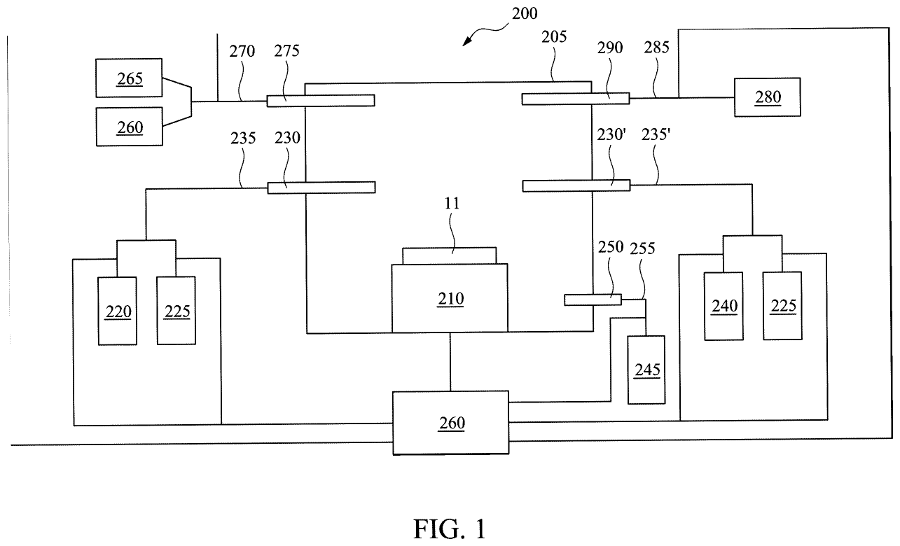

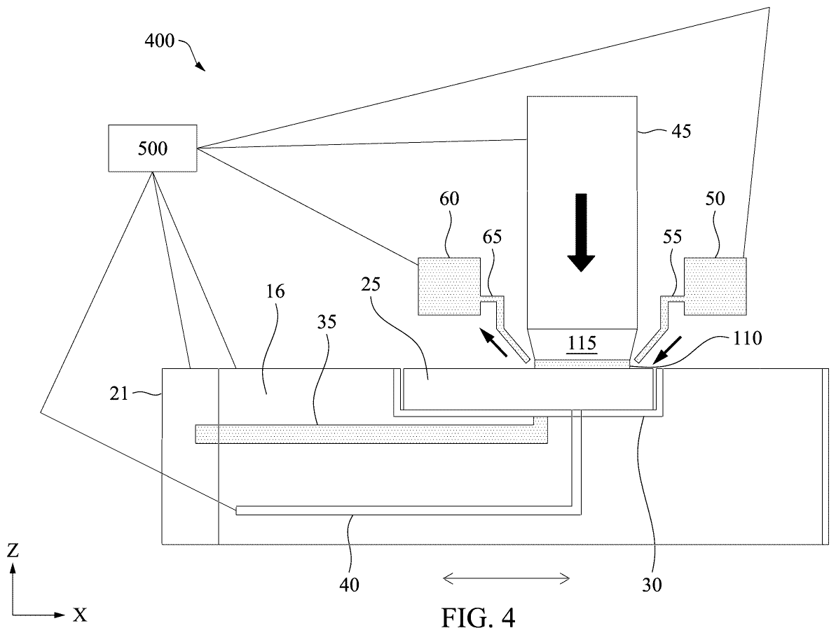

A metallic photoresist layer deposition apparatus 200 according to some embodiments of the disclosure is shown in FIG. 1. In some embodiments, the deposition apparatus 200 is an atomic layer deposition (ALD) or chemical vapor deposition (CVD) apparatus. The deposition apparatus 200 includes a vacuum chamber 205. A substrate support stage 210 in the vacuum chamber 205 supports a substrate 11, such as silicon wafer. In some embodiments, after application of the metallic photoresist layer to the substrate by the deposition apparatus 200, the metallic photoresist-coated wafer is further processed by an immersion photolithography apparatus 400 (FIG. 4).

In some embodiments, the substrate support stage 210 (FIG. 1) includes a heater or a chiller (not shown). A first precursor or compound gas supply 220 and carrier/purge gas supply 225 are connected to an inlet 230 in the chamber via a gas line 235, and a second precursor or compound gas supply 240 and carrier/purge gas supply 225 are connected to another inlet 230′ in the chamber via another gas line 235′ in some embodiments. The chamber is evacuated, and excess reactants and reaction byproducts are removed by a vacuum pump 245 via an outlet 250 and exhaust line 255. In some embodiments, the flow rate or pulses of precursor gases and carrier/purge gases, evacuation of excess reactants and reaction byproducts, pressure inside the vacuum chamber 205, and temperature of the vacuum chamber 205 or wafer support stage 210 are controlled by a controller 260 configured to control each of these parameters.

Depositing a metallic photoresist layer includes combining the first compound or first precursor and the second compound or second precursor in a vapor state to form the metallic photoresist composition in some embodiments. In some embodiments, the first compound or first precursor and the second compound or second precursor of the photoresist composition are introduced into the deposition chamber 205 (CVD chamber) at about the same time via the inlets 230, 230′. In some embodiments, the first compound or first precursor and second compound or second precursor are introduced into the deposition chamber 205 (ALD chamber) in an alternating manner via the inlets 230, 230′, i.e., first one compound or precursor then a second compound or precursor, and then subsequently alternately repeating the introduction of the one compound or precursor followed by the second compound or precursor.

In some embodiments, the deposition chamber 205 temperature ranges from about 30 °C to about 400 °C during the deposition operation, and between about 50 °C to about 250 °C in other embodiments. In some embodiments, the pressure in the deposition chamber 205 ranges from about 5 mTorr to about 100 Torr during the deposition operation, and between about 100 mTorr to about 10 Torr in other embodiments. In some embodiments, the plasma power is less than about 1000 W. In some embodiments, the plasma power ranges from about 100 W to about 900 W. In some embodiments, the flow rate of the first compound or precursor and the second compound or precursor ranges from about 100 sccm to about 1000 sccm. In some embodiments, the ratio of the flow of the metallic compound precursor to the second compound or precursor ranges from about 1:1 to about 1:5. At operating parameters outside the above-recited ranges, unsatisfactory metallic photoresist layers result in some embodiments. In some embodiments, the photoresist layer formation occurs in a single chamber (a one-pot layer formation).

In a CVD process according to some embodiments of the disclosure, two or more gas streams, in separate inlet paths 230, 235 and 230′, 235′, of a metallic precursor and a second precursor are introduced to the deposition chamber 205 of a CVD apparatus, where they mix and react in the gas phase, to form a reaction product. The streams are introduced using separate injection inlets 230, 230′ or a dual-plenum showerhead in some embodiments. The deposition apparatus is configured so that the streams of metallic precursor and second precursor are mixed in the chamber, allowing the metallic precursor and second precursor to react to form a reaction product. Without limiting the mechanism, function, or utility of the disclosure, it is believed that the product from the vapor-phase reaction becomes heavier in molecular weight and is then condensed or otherwise deposited onto the substrate 11.

In some embodiments, an ALD process is used to deposit the metallic photoresist layer. During ALD, a layer is grown on a substrate 11 by exposing the surface of the substrate to alternate gaseous compounds (or precursors). In contrast to CVD, the precursors are introduced as a series of sequential, non-overlapping pulses. In each of these pulses, the precursor molecules react with the surface in a self-limiting way, so that the reaction terminates once all the reactive sites on the surface are consumed. Consequently, the maximum amount of material deposited on the surface after a single exposure to all of the precursors (a so-called ALD cycle) is determined by the nature of the precursor-surface interaction.

In an embodiment of an ALD process, a metallic precursor is pulsed to deliver the metal-containing precursor to the substrate 11 surface in a first half reaction. In some embodiments, the metallic precursor reacts with a suitable underlying species (for example OH or NH functionality on the surface of the substrate) to form a new self-saturating surface. Excess unused reactants and the reaction by-products are removed, by an evacuation-pump down using a vacuum pump 245 and/or by a flowing an inert purge gas in some embodiments. Then, a second precursor, such as ammonia (NH₃), is pulsed to the deposition chamber in some embodiments. The NH₃ reacts with the metallic precursor on the substrate to obtain a reaction product photoresist on the substrate surface. The second precursor also forms self-saturating bonds with the underlying reactive species to provide another self-limiting and saturating second half reaction. A second purge is performed to remove unused reactants and the reaction by-products in some embodiments. Pulses of the first precursor and second precursor are alternated with intervening purge operations until the desired thickness of the metallic photoresist layer is achieved.

In some embodiments, the first and second compounds or precursors are delivered into the deposition chamber 205 with a carrier gas. The carrier gas, a purge gas, a deposition gas, or other process gas may contain nitrogen, hydrogen, argon, neon, helium, or combinations thereof.

In some embodiments, the metallic photoresist layer is formed to a thickness of about 0.5 nm to about 100 nm, and to a thickness of about 10 nm to about 50 nm in other embodiments. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the photoresist layers. In some embodiments, each metallic photoresist layer thickness is relatively uniform to facilitate processing. In some embodiments, the variation in thickness of the deposited photoresist layer varies by no more than +25% from the average thickness, in other embodiments each photoresist layer thickness varies by no more than +10% from the average photoresist layer thickness. In some embodiments, such as high uniformity depositions on larger substrates, the evaluation of the metallic photoresist layer uniformity may be evaluated with a 1 centimeter edge exclusion, i.e., the layer uniformity is not evaluated for portions of the coating within 1 centimeter of the edge. A person of ordinary skill in the art will recognize that additional ranges within the explicit ranges above are contemplated and are within the present disclosure.

In some embodiments, the metallic compound includes tin (Sn), antimony (Sb), indium (In), cesium (Cs), barium (Ba), lanthanum (La), cerium (Ce), silver (Ag), zirconium (Zr), zinc (Zn), hafnium (Hf), and/or titanium (Ti) as the metal component, however, the disclosure is not limited to these metals. In other embodiments, additional suitable metals include tellurium (Te), bismuth (Bi), vanadium (V), cobalt (Co), molybdenum (Mo), tungsten (W), aluminum (Al), gallium (Ga), silicon (Si), germanium (Ge), phosphorus (P), arsenic (As), yttrium (Y), lutetium (Lu), or combinations thereof. In some embodiments, the additional metals are used as alternatives to or in addition to the Sn, Sb, In, Cs, Ba, La, Ce, Ag, Zr, Zn, Hf, and/or Ti. The particular metal used may significantly influence the absorption of radiation. Therefore, the metal component can be selected based on the desired radiation and absorption cross section.

In embodiments of the present disclosure, the metallic photoresist includes a metallic core. The metal core type is selected from high photo absorption metal atoms including Sn, Sb, In, Cs, Ba, La, Ce, Ag, Zr, Zn, Hf, and/or Ti in oxide form or bound to a R linkage unit. In some embodiments, the metallic core includes metal oxides selected from hafnium oxide (Hf₄Oₓ), or zinc oxide (Zn₄Oₓ). In other embodiments, the metal core is selected from SnR₃(OR)₁, SnR₂(OR)₂, SnR₁(OR)₃, SnR₄, or Sn(OR)₄, wherein embodiments of the R1, R2, R3, and R4 linkage units independently include a 1-9 carbon (C1-C9) unbranched, C3-C9 branched, C3-C9 cyclic or noncyclic, saturated or unsaturated, aromatic or non-aromatic, unsubstituted or halogen-substituted group; or —S—; —P—; —P(O₂)—; —C(═O)S—; —C(═O)O—; —O—; —N—; —C(═O)N—; —SO₂O—; —SO₂S—; —SO—; —SO₂—; a carboxylic acid group, an ether group, a ketone group, an ester group, or an aryl group (e.g., phenyl). In some embodiments, the R1, R2, R3, and R4 linkage units include halogen substituents, such as iodine.

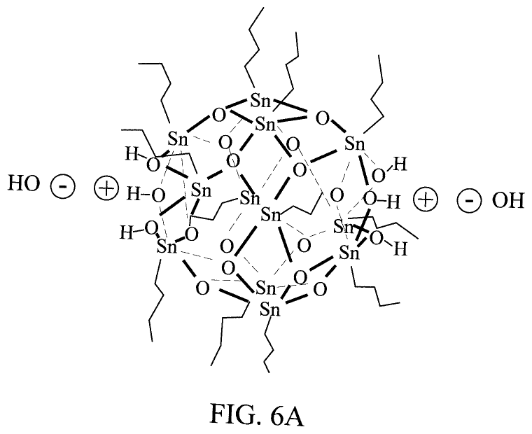

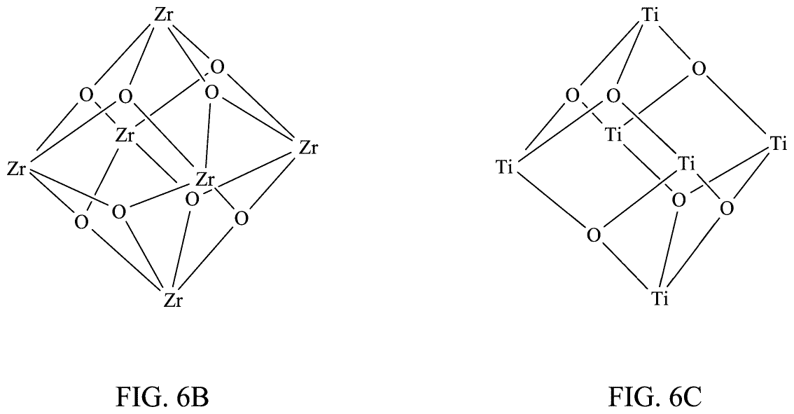

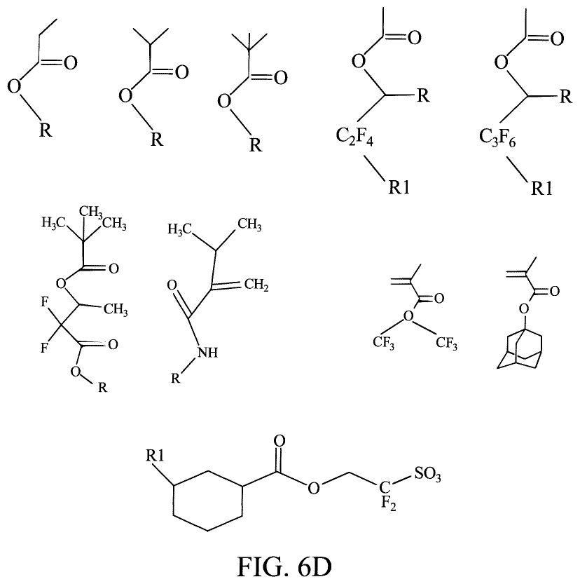

In some embodiments, metal-oxo cage compounds are used as the metal core. In some embodiments, a tin-oxo core structure surrounded by carbon ligands and hydroxide counterions is used. In some embodiments a carbon ligand R is cyclic or noncyclic, saturated, or unsaturated, substituted or substituted, or branched or unbranched 1-9 carbon unit (e.g., alkyl group, alkenyl group). The substituted 1-9 carbon unit can be substituted with halogen, —S—, —P—, —P(O₂)—, —C(═O)S—, —C(═O)O—, —O—, —N—, —C(═O)N—, —SO₂O—, —SO₂S—, —SO—, —SO₂—, carboxyl group, ether, ketone, ester, or aryl (e.g., phenyl). In some embodiments, the tin-oxo cage compound [(SnBu)₁₂O₁₄(OH)₆](OH)₂ is used as the metallic core, as shown in FIG. 6A.

In other embodiments, an octahedral metal oxo cluster is used as the metal core. In some examples, an octahedral zirconium (Zr) oxo cluster is used as the metal core. In other examples, an octahedral titanium (Ti) cluster is used as the metal core. In some embodiments, an octahedral Zr₆O₈ core or an octahedral Ti₆O₆ core is used with carboxylate ligands. In some embodiments, the Zr₆O₈ core of Zr₆O₄(OH)₄(OOCR)₁₂ is used with carboxylate ligands, as shown in FIG. 6B. In other embodiments, the Ti₆O₆ core of Ti₆O₆(OR)₆(OOCR′)₆ is used with carboxylate ligands, as shown in FIG. 6C.

In some embodiments, the metallic photoresist layer is formed by mixing the metal core compound in a solvent to form a metallic resist composition and dispensing the metallic resist composition onto the substrate 11. To aid in the mixing and dispensing of the photoresist, the solvent is chosen at least in part based upon the materials chosen for the metallic resist. In some embodiments, the solvent is chosen such that the metal core is evenly distributed or dispersed into the solvent and dispensed upon the layer to be patterned.

In some embodiments, the resist solvent is an organic solvent, and includes any suitable solvent such as propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), 2-heptanone (MAK), formic acid, acetic acid, propanoic acid, butanoic acid, or the like.

As one of ordinary skill in the art will recognize, the materials listed and described above as examples of materials that may be used for the solvent component of the metallic photoresist are merely illustrative and are not intended to limit the embodiments. Rather, any suitable solvent for the metallic photoresist material may be used to help mix and apply the photoresist. All such materials are fully intended to be included within the scope of the embodiments.

The photoresist layer deposition apparatus 200 illustrated in FIG. 1 is also used to apply a floating additive composition to the metallic photoresist layer in some embodiments. A floating additive composition supply 260 and carrier gas supply 265 are connected to an inlet 275 in the chamber 205 via a supply line 270. In some embodiments, the inlet 275 is configured to deliver the floating additive composition as a liquid spray or as an atomized vapor. In some embodiments, a purge gas supply 280 is connected to a purge gas inlet 290 via a gas supply line 285. In some embodiments, the chamber 205 is purged with the purge gas before the floating additive composition is introduced into the chamber 205. In some embodiments, the floating additive composition is introduced into the chamber 205 before the photoresist layer is formed, and in other embodiments, the floating additive composition is added after the photoresist layer is formed. In other embodiments, the floating additive composition is introduced into the chamber 205 substantially simultaneously with the introduction of the photoresist components, and the floating additive composition is applied directly to the photoresist layer while the photoresist layer is being formed. In some embodiments, the flow rate of the floating additive composition, carrier gas, or purge gas are also controlled by the controller 260 configured to control each of these parameters, along with the flow rate of the precursor gases and carrier/purge gases, evacuation of excess reactants and reaction byproducts, pressure inside the vacuum chamber 205, and temperature of the vacuum chamber 205 or wafer support stage 210.

In some embodiments of the present disclosure, the metallic photoresist is made of a solvent, and metallic core with 1 or more ligand. The ligand of the metallic photoresist initiates a crosslink chain reaction after light exposure for patterning. In some embodiments the metallic resist includes the metallic core, solvent, and floating additive. In some embodiments, the metallic core includes between 1 and 18 metal ion clusters and 1 to 18 ligand clusters.

In some embodiments, the metallic resist is formed by spin coating, CVD, PVD, ALD, or a chemical treatment. In some embodiments, the metallic resist including the floating additive has a thickness of about 0.5 nm to about 100 nm. In some examples, the floating additive is bound to the metal core or is blended with the metallic core. The combination of the metallic resist with the floating additive makes the metallic resist less susceptible to dissolving by the liquid medium of the immersion photolithography. In some embodiments, the floating additive is provided at about 0.01 weight percent (wt %) to about 30 wt % relative to the solvent.

In some embodiments, the floating additive material is blended in the solvent. In some embodiments, the floating additive is a monomer. Some examples of monomer units for the floating additive material are shown in FIG. 6D. In some embodiments, the monomer units of FIG. 6D include R and R1 linkage units selected from unbranched or branched, cyclic, saturated, 1 to about 30 carbon units with a hydrogen or halogen (e.g., alky, alkene) group, or —S—; —P—; —P(O₂)—; —C(═O)S—; —C(═O)O—; —O—; —N—; —C(═O)N—; —SO₂O—; —SO₂S—; —SO—, —SO₂—, a carboxylic acid group, an ether group, a ketone group, an ester group, or a phenyl group. In other embodiments, monomer units are joined together to form polymers. In some embodiments, the monomer units are connected with hydrogen to form single units. In some embodiments, monomer units of acrylates, methacrylates, hydroxystyrenes, acrylic acids, and siloxanes are joined together to form polymers.

In some embodiments, a linker is provided between the metallic core and the floating additive. In some embodiments, the linker has a structure of =OR/NR₂/F/Cl/Br/I, cyclic or noncyclic, saturated, 1 to 12 carbon units, with a hydrogen or halogen (e.g., alky, alkene) group; or —S—; —P—; —P(O₂)—; —C(═O)S—; —C(═O)O—; —O—; —N—; —C(═O)N—; —SO₂O—; —SO₂S—; —SO—, —SO₂—; or a carboxylic acid group, an ether group, a ketone group, an ester group, or a phenyl group.

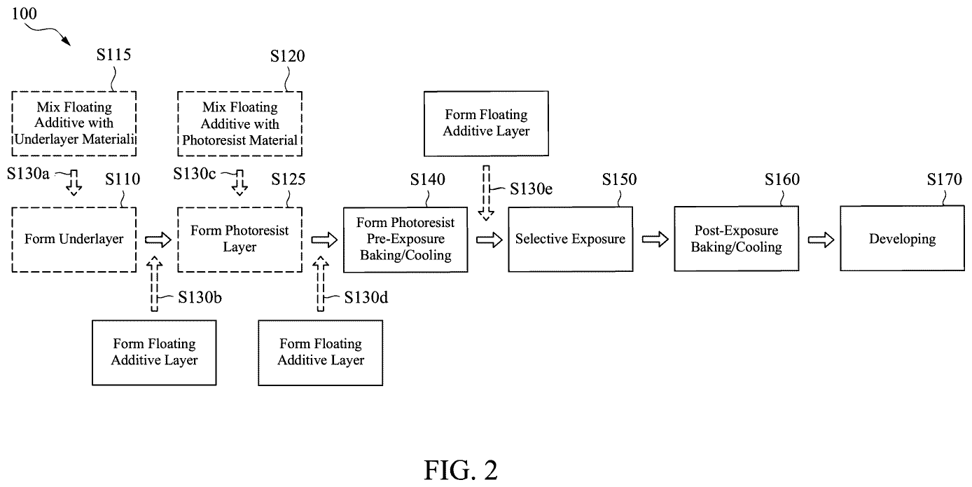

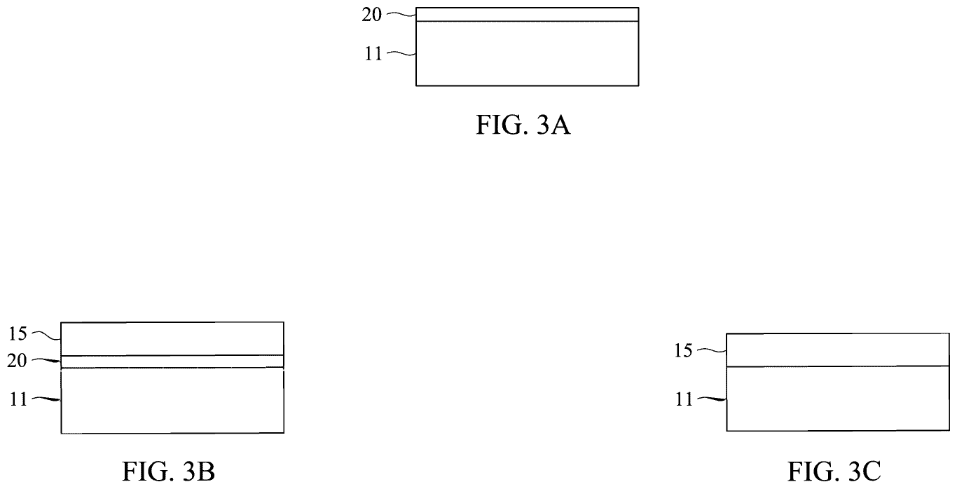

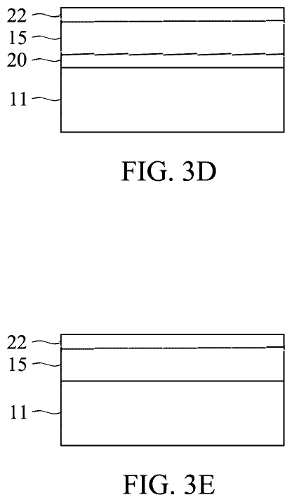

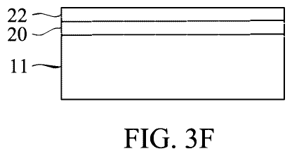

FIG. 2 illustrates a process flow 100 for manufacturing a semiconductor device according to embodiments of the disclosure. In some embodiments, a photoresist underlayer 20 is formed over the substrate 11 as shown in FIG. 3A, in a photoresist underlayer forming operation S110 as shown in FIG. 2. In some embodiments, a floating additive is mixed with the photoresist underlayer material in operation S115 before forming the underlayer 20 over the substrate 11. Then, in some embodiments, the underlayer material with the floating additive is applied to the substrate in operation S130a. In some embodiments, the underlayer material is applied by spin-coating techniques. During the spin-coating, phase separation occurs between the underlayer material and the floating additive, and the floating additive rises and covers or floats over the underlayer material layer. In some embodiments, the substrate is rotated at a spin rate of from about 100 rpm to about 3000 rpm during the material dispensing operation. In other embodiments, the substrate is rotated at a spin rate of from about 200 rpm to 1500 rpm. At spin rates below the disclosed range there may be insufficient phase separation. At spin rates above the disclosed range the underlayer may be formed too thin. In some embodiments, the rotation of the substrate continues for a time period after the photoresist underlayer is formed or the underlayer material dispensing is completed.

In some embodiments, the photoresist underlayer 20 is a bottom anti-reflective coating (BARC) layer. Any suitable BARC material may be used. Inorganic materials such as titanium, titanium dioxide, titanium nitride, chromium oxide, carbon, α-silicon, and organic materials such as a light-absorbing material and a polymer compound are used for the BARC layer in some embodiments. In some embodiments, materials for the BARC layer include magnesium fluoride, silicon nitride, silicon dioxide, titanium dioxide, and aluminum oxide.

Then, in operation S125 of FIG. 2, a metallic photoresist layer 15 is formed over the photoresist underlayer 20 as shown in FIG. 3B. In some embodiments, the metallic photoresist layer 15 is produced and applied by the metallic resist layer deposition apparatus 200 discussed above. In some embodiments, a baking operation is performed on the underlayer 20 to drive off solvents in the base composition before forming the photoresist layer over the underlayer 20 (FIG. 3B). In some embodiments, the metallic photoresist layer 15 is formed over the substrate 11 in operation S125, as shown in FIG. 3C. Then a floating additive layer 22 is formed over the metallic photoresist layer 15 in a floating additive layer applying operation S130d, as shown in FIG. 3D and FIG. 3E. FIG. 3D illustrates an embodiment of a stacked structure where the underlayer 20 is formed below the metallic photoresist layer 15 and a floating additive layer is formed over the metallic photoresist layer 15. FIG. 3E illustrates an embodiment of a stacked structure where the floating additive layer 22 is formed only over the upper surface of the metallic photoresist layer 15. In some embodiments, the floating additive composition is mixed with the photoresist material composition in operation S120 before forming the metallic photoresist layer 15. The floating additive/photoresist material composition is then applied to the substrate 11 or photoresist underlayer 20 in operation S130c in a spin coating operation to separate the floating additive from the photoresist material, thereby forming a floating additive layer 22 over the metallic photoresist layer 15. In some embodiments, the spin coating operation is performed at a spin rate of from about 100 rpm to about 3000 rpm during the photoresist/floating additive composition dispensing operation, and at a spin rate of about 200 rpm to 1500 rpm, similar to the underlayer formation operation. In other embodiments, the photoresist underlayer 20 is formed, and then, a floating additive layer 22 is formed over the underlayer 20 in operation S130b (FIG. 3F).

In other embodiments, the operation S125 of forming a metallic photoresist layer is performed by a vapor phase deposition operation. In some embodiments, the vapor phase deposition operation includes atomic layer deposition (ALD) and chemical vapor deposition (CVD). In some embodiments, the ALD includes plasma-enhanced atomic layer deposition (PE-ALD); the CVD includes plasma-enhanced chemical vapor deposition (PE-CVD), metal-organic chemical vapor deposition (MO-CVD), atmospheric pressure chemical vapor deposition (AP-CVD), and low pressure chemical vapor deposition (LP-CVD).

In other embodiments, the floating additive layer 22 is formed by chemical vapor deposition (CVD), physical vapor deposition (PVD), or atomic layer deposition (ALD) deposition. In other embodiments, the floating additive layer 22 is formed by a spray mist technique or through gas, liquid, or solid chemical treatment.

In some embodiments, the underlayer 20 and floating additive layer 22 are formed in a chamber, such as a vacuum chamber 205 as shown in FIG. 1. In some embodiments, the vacuum chamber 205 is used in a CVD, PVD, or ALD operation. In some embodiments, the chamber 205 is the same chamber in which the metallic photoresist layer 15 is formed. In other embodiments, the chamber that the underlayer and floating additive layer are formed in is a different chamber than the one in which the photoresist layer is formed. In some embodiments, the metallic photoresist is formed under ambient conditions.

In some embodiments, a gas purge of the chamber 205 is performed before or after the underlayer 20 and floating additive layer 22 or the metallic photoresist layer 15 are formed. In some embodiments, the chamber 205 is purged with one or more of carbon dioxide, nitrogen, helium, neon, argon, or dry air, where dry air has a dewpoint of about −40 °C or lower. In other embodiments, the humidity of the purge air is varied depending on process requirements, to between about 0 to about 100% relative humidity.

In some embodiments, a pre-exposure baking operation S140 is performed to drive off solvents in the metallic photoresist layer 15 or to cure the metallic photoresist layer 15. In some embodiments, the baking operation is performed in a chamber 205, such as a vacuum chamber. In some embodiments, the metallic photoresist layer 15 is heated at a temperature ranging from about 40 °C to about 300 °C for about 10 seconds to about 10 minutes. After the pre-exposure baking operation S140, the photoresist-coated substrate is cooled in a cooling operation. In some embodiments, the heating and cooling is performed using a heater/chiller (not shown). In some embodiments, the heater/chiller is a hot plate that includes internal coolant flow channels. The heating or cooling is controlled by the controller 260 in some embodiments. Likewise, heating, and cooling operations may be formed after forming the underlayer layer 20 (see FIG. 3A) and after forming the floating additive layer 22 (see FIGS. 3D and 3E).

In some embodiments, the floating additive layer 22 is formed after the baking and cooling operations S140. The floating additive layer material is applied to the metallic photoresist layer 15 in a floating additive layer application operation S130e after the pre-exposure baking/cooling operations S140 and before a selective exposure of the metallic photoresist layer 15 to actinic radiation S150 in some embodiments. In some embodiments, the exposure to actinic radiation is conducted by placing the photoresist-coated substrate in an immersion photolithography apparatus (FIG. 4).

FIG. 4 is a schematic cross-sectional illustration of an immersion photolithography apparatus 400 according to some embodiments of the disclosure. The apparatus includes a movable wafer stage 16 incorporated with vacuum channels 40 for holding and fixing the photoresist-coated substrate 25 onto a wafer table 30 on the wafer stage 16. An immersion fluid 110 is located on top of the photoresist-coated substrate 25 displacing the entire volume of space between the photoresist-coated substrate 25 and the last objective lens element 115 of the photolithography apparatus's light projection system 45. The immersion fluid 110 is in direct contact with both the top surface of the photoresist-coated substrate 25 and the lower surface of the objective lens element 115.

The immersion fluid 110 is any suitable liquid having an index of refraction greater than 1. In some embodiments, the immersion fluid 110 is water, an aqueous solution, or a non-aqueous liquid or solution. In some embodiments, the non-aqueous liquid includes hydrocarbons and derivatives thereof, including but not limited to, cyclic alkanes and acyclic alkanes (e.g. dodecane, hexane, pentane, hexadecane, cyclohexane, bicyclohexane, tricyclohexane, decahydronaphthalene, and cyclopentane; fluorinated (partially or fully) hydrocarbons and derivatives thereof (e.g., perfluorocyclohexane and perfluorodecalin); SFs-functionalized hydrocarbons; halocarbons (e.g. Freon 113); ethers (e.g., ethyl ether (Et₂O), tetrahydrofuran (THE), ethylene glycol and derivatives thereof, monomethyl ether, or 2-methoxyethyl ether (diglyme)), and esters and derivatives thereof (e.g. sodium octanoate and sodium perfluorooctanoate). Still further exemplary fluids include lactates; pyruvates; diols; ketones, including, acetone, cyclohexanone, N-methyl pyrrolidone (NMP), and methyl ethyl ketone. Other exemplary non-aqueous fluids include amides such as, but not limited to, dimethylformamide, dimethylacetamide, acetic acid anhydride, propionic acid anhydride, and the like. Exemplary non-aqueous fluids can include, but are not limited to, sulfur-containing compounds such as mercaptans (e.g., lauryl mercaptan), sulfones (e.g., dimethyl sulfone, diphenyl sulfone, sulfoxides (e.g., dimethyl sulfoxide). In addition, the non-aqueous fluids include alcohols such as, propylene glycol propyl ether (PGPE), methanol, tetrahydrofurfuryl alcohol, 1-methylcyclohexanol, cyclohexanol, 2-methylcyclohexanol, adamantanemethanol, cyclopentanol, dimethyl-3-heptanol, dimethyl-4-heptanol, dodecanol, oleyl alcohol, pentanol, 1,5-pentanediol, 1,6-hexanediol, 1,4-butanediol, 1,2-propylene glycol, 1,3-propylene glycol, 1-dodecanol, cyclooctane, ethanol, 3-heptanol, 2-methyl-1-pentanol, 5-methyl-2-hexanol, cis-2-methylcyclohexanol, 3-hexanol, 2-heptanol, 2-hexanol, 2,3-dimethyl-3-pentanol, propylene glycol methyl ether acetate (PGMEA), ethylene glycol and derivatives thereof, polyethylene glycol and derivatives thereof, isopropyl alcohol (IPA), propylene glycol n-butyl ether (PGBE), 1-butoxy-2-propanol, 2-methyl-3-pentanol, 2-butoxyethanol, 1-pentanol, propylene glycol methyl ether, 3,6-dimethyl-3,6-octanol, maltose, sorbitol, mannitol, super, fully, and partially hydrolyzed poly(vinyl) alcohol, 1,3-butanediol, glycerol and derivatives thereof such as thioglycerol. The immersion fluid 110 may include an acid such as sulfuric acid, lactic acid, octanoate acid, polyphosphoric acid, phosphoric acid, hexafluorophosphoric acid, tartaric acid, methane sulfonic acid, trifluoromethane sulfonic acid, dichloroacetic acid, propionic acid, and citric acid. The non-aqueous fluid may include an ester, such as ethyl acetate. Other suitable non-aqueous fluids include a silicone oil. Other non-aqueous fluids include 1,4-dioxane, 1,3-dioxolane, ethylene carbonate, propylene carbonate, and m-cresol. The non-aqueous fluids enumerated above may be used alone, in combination with one or more other non-aqueous fluids, or in combination with an aqueous fluid.

In some embodiments, the immersion fluid 110 may comprise a mixture of at least one aqueous fluid and at least one non-aqueous fluid. In these embodiments, the immersion fluid 110 may contain at least one non-aqueous fluid that is miscible in the aqueous fluid or is water miscible. The amount of non-aqueous fluid within the immersion fluid may range from about 1 to about 99%, or from about 1 to about 50% by weight with the balance of the carrier medium within the immersion fluid 110 comprising an aqueous fluid. Examples of water-miscible non-aqueous fluids include, but are not limited to, methanol, ethanol, isopropyl alcohol, glycerol, ethylene glycol and derivatives thereof, polyethylene glycol and derivatives thereof, and THE.

As shown in FIG. 4, two fluid reservoirs 50, 60 are configured to deliver the immersion fluid 110 to the region between the last objective lens element 115 and the photoresist-coated substrate 25 that includes the floating additive layer 22 (FIGS. 3D and 3E). A fluid supply reservoir 50 supplies and injects the immersion fluid 110 through an immersion fluid supply line 55 into the area under the objective lens element 115. The injected immersion fluid 110 is either held by capillary forces in the immersion area or contained within a fixture (not shown) moving with the lens. A thickness of the immersion fluid 110 between the objective lens element 115 and the photoresist-coated wafer 25 is between about 1 mm to about 2 mm. A fluid recovery reservoir 60 recovers the output immersion fluid flow from the area between the objective lens element 115 and the photoresist-coated substrate 25 via an immersion fluid recovery line 65. The downward arrow located over the light projection system 45 represents the direction of and the transmission of the pattern image-exposing actinic radiation through the last objective lens element 115 and through the immersion fluid 110 to the photoresist-coated substrate 25. During normal operation of the immersion lithography printing of the photoresist-coated substrate 25, the wafer stage 16 moves to position each exposure target area of the wafer under the fixed locations of the immersion fluid 110, the fluid reservoirs 50, 60, the objective lens element 115, and the pattern image-exposing radiation.

In immersion photolithography, the wafer stage 16 moves rapidly during the exposure operation. In some embodiments the wafer stage 16 scan speed is equal to or greater than 800 mm/s. The arrows below the wafer stage 16 illustrate the motion of the wafer stage 16 along the x axis. Heat is generated in the wafer stage 16 and wafer table 30 during the photolithographic exposure operations. The wafer stage 16 and wafer table 30 are cooled during the exposure by flowing or pulsing a coolant or cooling fluid through coolant or cooling fluid lines or conduits 35 in the wafer stage 16. The pressure of the cooling fluid or coolant flowing through the wafer stage 16 is monitored by pressure sensors in a pressure compensator 21 attached to a side of the wafer stage 16 in some embodiments.

A controller 500 monitors and controls the motion and positioning of the wafer stage 16 in some embodiments. In some embodiments, the controller 500 monitors the pressure of the cooling fluid or coolant in the pressure compensator 21. The controller 500 also controls the application and release of a vacuum in the vacuum line 40 for securing or releasing a wafer in some embodiments. In some embodiments, the controller 500 controls the raising and lowering of wafer support pins (not shown) to receive wafers onto the wafer table 30 or release the wafers from the wafer table 30. The controller 500 further controls the light projection system 45 and controls the exposure of the photoresist-coated substrate 25 to actinic radiation in some embodiments. Furthermore, in some embodiments, the controller monitors the immersion fluid level in the fluid reservoirs 50, 60 and controls the dispensing and recovery of the immersion fluid 110.

After the pre-exposure baking/cooling operations S140 (FIG. 2) of the metallic photoresist layer 15, the metallic photoresist layer 15 is selectively exposed to actinic radiation in operation S150. In some embodiments, the metallic photoresist layer 15 is selectively exposed to ultraviolet radiation. In some embodiments, the radiation is deep ultraviolet radiation, such as an ArF excimer laser light (wavelength of 193 nm) used in the immersion photolithography apparatus 400. In other embodiments, an F₂ excimer laser light (wavelength of 157 nm), or extreme ultraviolet (EUV) radiation, such as a CO₂ laser-excited Sn plasma (wavelength of 13.5 nm) is used. In other embodiments, the radiation is electromagnetic radiation, such as g-line (wavelength of about 436 nm) or i-line (wavelength of about 365 nm), or an electron beam, or the like. In some embodiments, the radiation source is selected from the group consisting of a mercury vapor lamp, xenon lamp, carbon arc lamp, a KrF excimer laser light (wavelength of 248 nm).

The metallic photoresist layer 15 is a photosensitive layer that is patterned by exposure to actinic radiation. Typically, the chemical properties of the photoresist regions struck by incident radiation change in a manner that depends on the type of photoresist used. The metallic photoresist layers 15 may be positive tone resists or negative tone resists. A positive tone resist refers to a photoresist material that when exposed to actinic radiation (e.g., UV light or e-beam) becomes soluble in a developer, while the region of the photoresist that is non-exposed (or exposed less) is insoluble in the developer. A negative tone resist, on the other hand, refers to a photoresist material that when exposed to actinic radiation becomes insoluble in the developer, while the region of the photoresist that is non-exposed (or exposed less) is soluble in the developer. The region of a negative tone resist that becomes insoluble upon exposure to radiation may become insoluble due to a cross-linking reaction caused by the exposure to radiation. In some embodiments, the resist is a negative tone developed (NTD) resist. In an NTD resist, the portions of the photoresist layer exposed to actinic radiation do not crosslink, however, a developer is selected to selectively dissolve the unexposed portions of the photoresist layer, so that the exposed portions remain on the substrate. In some embodiments, the NTD developer is an organic developer such as n-butyl acetate.

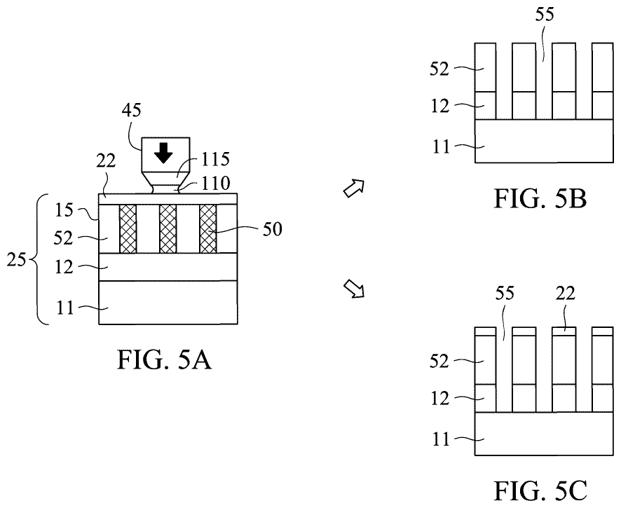

As shown in FIG. 5A, the downward arrow located over the light projection system 45 represents the direction of and the transmission of the pattern image-exposing actinic radiation through the last objective lens element 115 and through the immersion fluid 110 to the photoresist-coated wafer 25. During normal operation of the immersion lithography printing of the photoresist-coated wafer 25, the wafer stage 16 (FIG. 4) moves to position each exposure target area of the wafer under the fixed locations of the immersion fluid 110, the fluid reservoirs 50, 60, the objective lens element 115, and the pattern image-exposing radiation.

In FIG. 5A, the photoresist-coated wafer 25 includes a substate 11, target layer 12, and metallic photoresist layer 15 with floating additive layer 22. In some embodiments, the target layer 12 is disposed over the substrate 11. The desired patterning layout is transferred from the photoresist layer 15 into the target layer 12. In some embodiments, the target layer 12 is a metallization layer or a dielectric layer, such as a passivation layer, disposed over a metallization layer. In embodiments where the target layer 12 is a metallization layer, the target layer 12 is formed of a conductive material using metallization processes, and metal deposition techniques, including chemical vapor deposition, atomic layer deposition, and physical vapor deposition (sputtering). Likewise, if the target layer 12 is a dielectric layer, the target layer 12 is formed by dielectric layer formation techniques, including thermal oxidation, CVD, ALD, and PVD. In the embodiment of FIG. 5A, the upper surface of the metallic photoresist layer 15 includes a floating additive layer 22. Although not shown in FIG. 5A, an underlayer layer 20 (e.g., BARC layer) is included below the metallic photoresist layer 15 and above the target layer 12 in some embodiments.

In some embodiments, the selective exposure of the metallic photoresist layer 15 to form exposed regions 50 and unexposed regions 52 (FIG. 5A) is performed using ArF immersion lithography. The region of the metallic photoresist layer exposed to radiation 50 undergoes a chemical reaction thereby changing its solubility in a subsequently applied developer relative to the region of the photoresist layer 52 not exposed to radiation. In some embodiments, the portion of the photoresist layer 50 exposed to radiation becomes more soluble in the developer.

The selectively exposed metallic photoresist layer 15 subsequently undergoes a post-exposure baking (PEB) or cooling operation S160 (FIG. 2). In some embodiments, the metallic photoresist layer 15 is heated or cooled at a temperature ranging from about −30 °C to about 300 °C during the post-exposure baking or cooling operation S160. In some embodiments, the temperature is controlled using the heater/chiller and a controller 500. In other embodiments, the metallic photoresist layer 15 is heated at a temperature ranging from about 40 °C to about 160 °C for about 20 s to about 120 s. The post-exposure baking may be used to assist in the generating, dispersing, and reacting of the acid/base/free radical generated from the impingement of the radiation upon the metallic photoresist layer 15 during the exposure. Such assistance helps to create or enhance chemical reactions, which generate chemical differences between the exposed region 50 and the unexposed region 52 within the photoresist layer.

The selectively exposed photoresist layer is subsequently developed by applying a developer to the selectively exposed photoresist layer in operation S170. A developer is supplied from a dispenser to the metallic photoresist layer 15. In some embodiments, the exposed region 50 of the photoresist layer, the exposed region of the floating additive layer 22 are removed by the developer forming a pattern of openings 55 in the metallic photoresist layer 15, as shown in FIGS. 5A and 5B. In the embodiment of FIG. 5B, the floating additive layer 22 is removed from the exposed region 50 and unexposed region 52 by the developer. In the embodiment of FIG. 5C, the floating additive layer 22 is removed by the developer from the exposed region 50 but remains over the unexposed region 52 by the developer. In some embodiments, the pattern of openings 55 in the patterned metallic photoresist layer 15 extends into the target layer 12 thereby transferring the pattern in the metallic photoresist layer 15 into the target layer 12, as shown in FIGS. 5A and 5B. The pattern is extended into the target layer by etching, using one or more suitable etchants. In some embodiments, the etching operation removes remaining portions of the BARC underlayer. The photoresist is at least partially removed during the etching operation in some embodiments. In other embodiments, the photoresist, and any remaining portions of the BARC underlayer under the photoresist layer are removed after etching by using a suitable photoresist stripper solvent or by a photoresist ashing operation.

In the embodiment shown in FIGS. 5B and 5C, a positive tone photoresist is described. In other embodiments a negative tone photoresist is used. The photoresist layer 15 is a photosensitive layer that is patterned by exposure to radiation. Typically, the chemical properties of the photoresist regions struck by incident radiation change in a manner that depends on the type of photoresist used. Embodiments of the present disclosure include photoresist layers 15 that are positive tone resists or negative tone resists. A positive tone resist refers to a photoresist material that when exposed to actinic radiation (e.g., UV light or e-beam) becomes soluble in a developer, while the region of the photoresist that is non-exposed (or exposed less) is insoluble in the developer. A negative tone resist, on the other hand, refers to a photoresist material that when exposed to actinic radiation becomes insoluble in the developer, while the region of the photoresist that is non-exposed (or exposed less) is soluble in the developer. The region of a negative tone resist that becomes insoluble upon exposure to radiation may become insoluble due to a cross-linking reaction caused by the exposure to radiation. In some embodiments, the resist is a negative tone developed (NTD) resist. In an NTD resist, the portions of the photoresist layer exposed to actinic radiation do not crosslink, however, a developer is selected to selectively dissolve the unexposed portions of the photoresist layer, so that the exposed portions remain on the substrate. In some embodiments, the NTD develop is an organic developer such as n-butyl acetate.

In some embodiments of the disclosure, the developer composition includes an ammonium compound. In some embodiments, suitable bases include tetramethylammonium hydroxide, tetraethylammonium hydroxide, tetrapropylammonium hydroxide, and tetrabutylammonium hydroxide, and combinations thereof; or inorganic bases selected from the group consisting of ammonium hydroxide, ammonium sulfamate, ammonium carbamate, NaOH, KOH, LiOH, Ca(OH)₂, Ba(OH)₂, Na₂CO₃, Mg(OH)₂, RbOH, CsOH, Sr(OH)₂ and combinations thereof or inorganic bases selected from the group consisting of ammonia, ammonium sulfamate, ammonium carbamate, and combinations thereof. In some embodiments, the concentration of the base is about 1 ppm to about 30 wt. % based on a total weight of the developer composition.

In some embodiments, the developer composition includes water or ethylene glycol at a concentration of about 0.001 wt. % to about 30 wt. % based on a total weight of the developer composition.

In some embodiments, the photoresist developer composition includes a surfactant in a concentration range of from about 0.001 wt. % to about less than 5 wt. % based on a total weight of the developer composition to increase the solubility and reduce the surface tension on the substrate. In other embodiments, the concentration of the surfactant ranges from about 0.01 wt. % to about 1 wt. % based on the total weight of the developer composition.

At concentrations of the developer composition components outside the disclosed ranges, developer composition performance and development efficiency may be reduced, leading to increased photoresist residue and scum in the photoresist pattern, and increased line width roughness and line edge roughness.

In some embodiments, the developer is applied to the metallic photoresist layer 15 using a spin-on process. In the spin-on process, the developer is applied to the metallic photoresist layer 15 from above the metallic photoresist layer 15 while the photoresist coated substrate is rotated. In some embodiments, the developer is supplied at a rate of between about 5 ml/min and about 800 ml/min, while the photoresist coated substrate 11 is rotated at a speed of between about 100 rpm and about 2000 rpm. In some embodiments, the developer is at a temperature of between about 20 °C and about 75 °C during the development operation. The development operation continues for about 10 seconds to about 10 minutes in some embodiments.

While the spin-on operation is one suitable method for developing the metallic photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

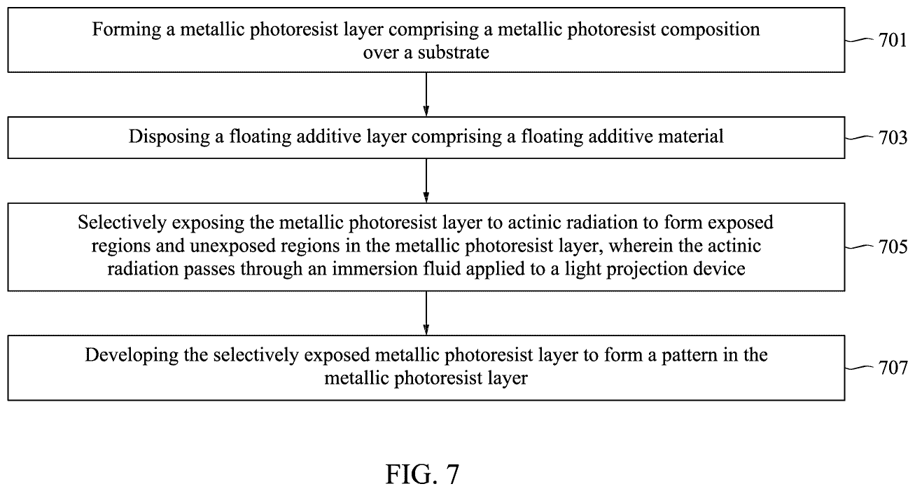

FIG. 7 is flowchart for a method of manufacturing a semiconductor device. The method includes step 701 of forming a metallic photoresist layer comprising a metallic photoresist composition over a substrate. Step 703 includes disposing a floating additive layer comprising a floating additive material. Step 705 includes selectively exposing the metallic photoresist layer to actinic radiation to form exposed regions and unexposed regions in the metallic photoresist layer. In some embodiments, the actinic radiation passes through an immersion fluid applied to a light projection device. Step 707 includes developing the selectively exposed metallic photoresist layer to form a pattern in the metallic photoresist layer.

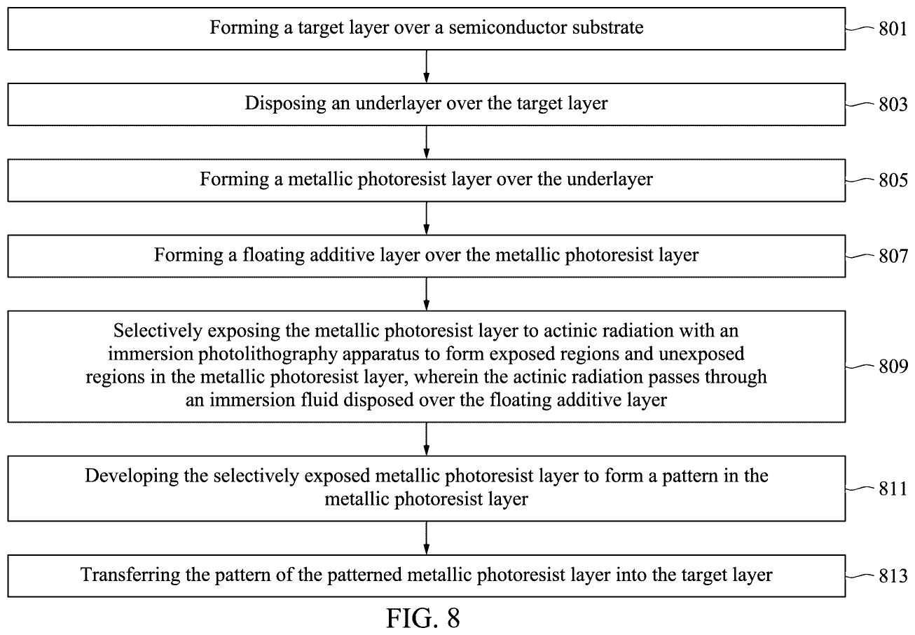

FIG. 8 is a flow chart for a method of manufacturing a semiconductor device. The method includes the step 801 of forming a target layer over a semiconductor substrate. The method includes the step 803 of disposing an underlayer over the target layer. The method includes the step 805 of forming a metallic photoresist layer over the underlayer. The method includes the step 807 of forming a floating additive layer over the metallic photoresist layer. The method includes step 809 of selectively exposing the metallic photoresist layer to actinic radiation with an immersion photolithography apparatus to form exposed regions and unexposed regions in the metallic photoresist layer. In some embodiments, the actinic radiation passes through an immersion fluid disposed over the floating additive layer. The method includes the step 811 of developing the selectively exposed metallic photoresist layer to form a pattern in the metallic photoresist layer. The method includes the step 813 of transferring the pattern of the patterned metallic photoresist layer into the target layer.

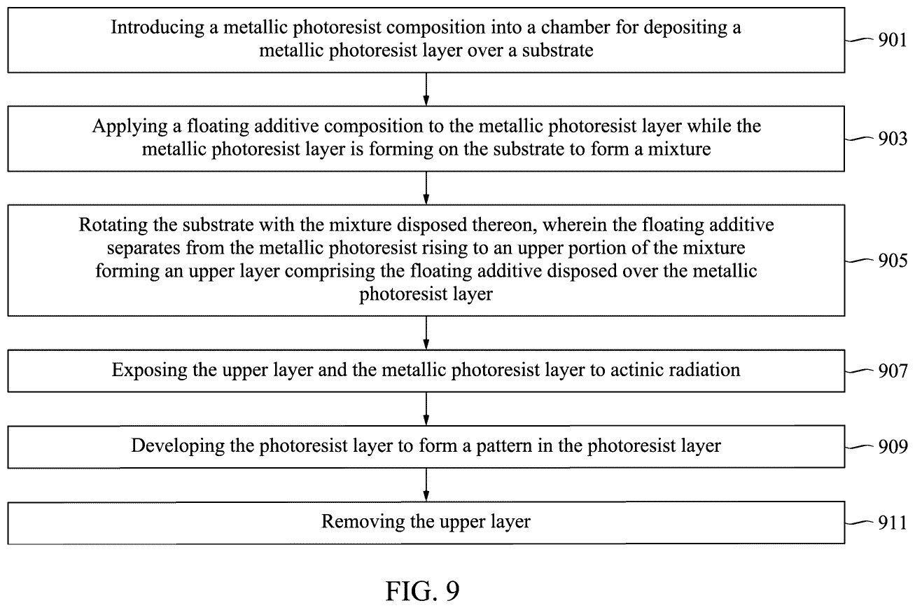

FIG. 9 is a flow chart for a method of forming a photoresist pattern. The method includes the step 901 of introducing a metallic photoresist composition into a chamber for depositing a metallic photoresist layer over a substrate. The method includes step 903 of applying a floating additive composition to the metallic photoresist layer while the metallic photoresist layer is forming on the substrate to form a mixture. The method includes the step 905 of rotating the substrate with the mixture disposed thereon. In some embodiments, the floating additive separates from the metallic photoresist rising to an upper portion of the mixture forming an upper layer comprising the floating additive disposed over the metallic photoresist layer. The method includes the step 907 of exposing the upper layer and the metallic photoresist layer to actinic radiation. The method includes the step 909 of developing the photoresist layer to form a pattern in the photoresist layer. The method includes the step 911 of removing the upper layer.

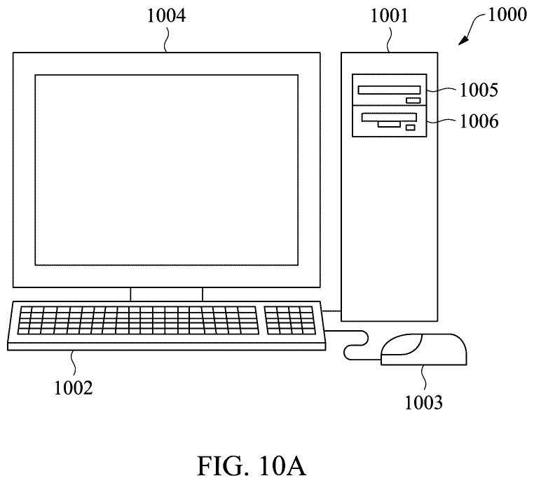

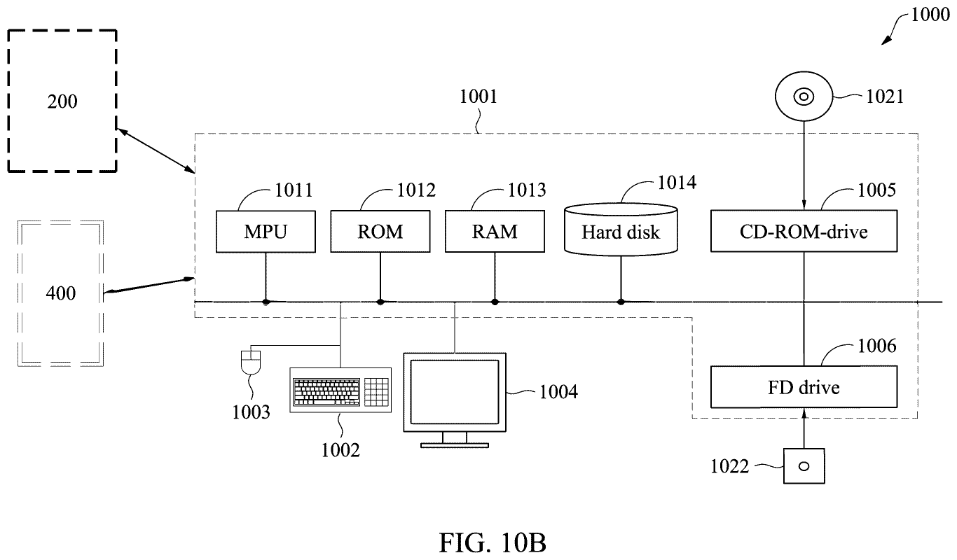

In some embodiments, each controller 260 (FIG. 1) and controller 500 (FIG. 4) is a computer system. FIG. 10A and FIG. 10B illustrate a computer system 1000 for controlling a metallic resist layer deposition apparatus 200, an immersion photolithography apparatus 400, and their respective components in accordance with various embodiments of the disclosure. FIG. 10A is a schematic view of the computer system 1000 that controls the metallic resist layer deposition apparatus 200 and immersion photolithography apparatus 400 and their respective components.

As shown in FIG. 10A, the computer system 1000 is provided with a computer 1001 including an optical disk read only memory (e.g., CD-ROM or DVD-ROM) drive 1005 and a magnetic disk drive 1006, a keyboard 1002, a mouse 1003 (or other similar input device), and a monitor 1004 in some embodiments.

FIG. 10B is a diagram showing an internal configuration of the computer system 1000. In FIG. 10B, the computer 1001 is provided with, in addition to the optical disk drive 1005 and the magnetic disk drive 1006, one or more processors 1011, such as a micro-processor unit (MP) or a central processing unit (CPU); a read-only memory (ROM) 1012 in which a program, such as a boot up program is stored; a random access memory (RAM) 1013 that is connected to the processors 1011 and in which a command of an application program is temporarily stored, and a temporary electronic storage area is provided; a hard disk 1014 in which an application program, an operating system program, and data are stored; and a data communication bus 1015 that connects the processors 1011, the ROM 1012, and the like. Note that the computer 1001 may include a network card (not shown) for providing a connection to a computer network such as a local area network (LAN), wide area network (WAN) or any other useful computer network for communicating data used by the computer system 1000 for the immersion photolithography apparatus 400 and metallic resist layer deposition apparatus 200. In various embodiments, the controller 500 communicates via wireless or hardwired connection to the immersion photolithography apparatus 400 and metallic resist layer deposition apparatus 200 and their respective components.

The programs for causing the computer system 1000 to execute the method for controlling immersion photolithography apparatus 400 and the metallic resist layer deposition apparatus 200 are stored in an optical disk 1021 or a magnetic disk 1022, which is inserted into the optical disk drive 1005 or the magnetic disk drive 1006 and transmitted to the hard disk 1014. Alternatively, the programs are transmitted via a network (not shown) to the computer system 1000 and stored in the hard disk 1014. At the time of execution, the programs are loaded into the RAM 1013. The programs are loaded from the optical disk 1021 or the magnetic disk 1022, or directly from a network in various embodiments.

The stored programs do not necessarily have to include, for example, an operating system (OS) or a third-party program to cause the computer 1001 to execute the methods disclosed herein. The program may only include a command portion to call an appropriate function (module) in a controlled mode and obtain desired results in some embodiments. In various embodiments described herein, the controller 500 is in communication with the immersion photolithography apparatus 400 to control various functions thereof. In other embodiments, the controller 260 is in communication with the metallic resist layer deposition apparatus 200 to control various functions thereof.

The controllers 260 and 500 are configured to provide control data to their respective system components and receive process and/or status data from those respective system components. For example, in some embodiments, the controllers 260 and 500 each comprises a microprocessor, a memory (e.g., volatile or non-volatile memory), and a digital I/O port capable of generating control voltages sufficient to communicate and activate inputs to the processing system, as well as monitor outputs from the immersion photolithography apparatus 400 and the metallic resist layer deposition apparatus 200. In addition, a program stored in the memory is utilized to control the aforementioned components of the immersion photolithography apparatus 400 and metallic resist layer deposition apparatus 200 according to process recipes.

Furthermore, the controllers 260 and 500 are both configured to analyze the process and/or status data, to compare the process and/or status data with target process and/or status data, and to use the comparison to change a process and/or control a system component. In addition, the controllers 260 and 500 are both configured to analyze the process and/or status data, to compare the process and/or status data with historical process and/or status data, and to use the comparison to predict, prevent, and/or declare a fault or alarm.

The novel metallic photoresist with floating additive layer improves etching selectivity, improves process critical dimension stability, and reduces critical dimension variation by more than 10%, thus, providing a cost savings and increased device yield. The ArF immersion photolithography techniques utilizing the metal photoresist with floating additive layer decreases solubility of the metallic resist during ArF immersion photolithography operations. The floating additive protects the metallic photoresist from dissolving by the immersion fluid during ArF immersion photolithography. It will be understood that not all advantages have been necessarily discussed herein, no particular advantage is required for all embodiments or examples, and other embodiments or examples may offer different advantages.

In one embodiment of the disclosure, a method of manufacturing a semiconductor device is provided. The method includes forming a metallic photoresist layer comprising a metallic photoresist composition over a substrate. The method includes disposing a floating additive layer comprising a floating additive material. The method includes selectively exposing the metallic photoresist layer to actinic radiation to form exposed regions and unexposed regions in the metallic photoresist layer. In some embodiments, the actinic radiation passes through an immersion fluid applied to a light projection device. The method includes developing the selectively exposed metallic photoresist layer to form a pattern in the metallic photoresist layer.

In some embodiments, the metallic photoresist layer is formed in a vacuum chamber or under ambient conditions. In other embodiments, the floating additive is added to the metallic photoresist composition before forming the metallic photoresist layer. In some embodiments, the floating additive layer includes the floating additive is formed over the metallic photoresist layer before selectively exposing the metallic photoresist layer to the actinic radiation. In other embodiments, the method includes forming an underlayer over the substrate before forming the metallic photoresist layer, wherein the underlayer includes a BARC. In some embodiments, the metallic photoresist composition includes a metallic core including a metal-oxo cage compound. In some embodiments, the metal-oxo cage compound include a tin-oxo core structure including carbon ligands and hydroxide counterions. In some embodiments, the metallic photoresist composition includes a metallic core including an octahedral metal-oxo cluster. In other embodiments, the octahedral metal-oxo cluster includes zirconium or titanium. In some embodiments, the floating additive layer is formed by spin coating, chemical vapor deposition, plasma vapor deposition, or atomic layer deposition. In some embodiments, a thickness of the metallic photoresist layer and the floating additive layer ranges from 0.5 to 100 nm. In other embodiments, the floating additive material is selected from the group consisting of:

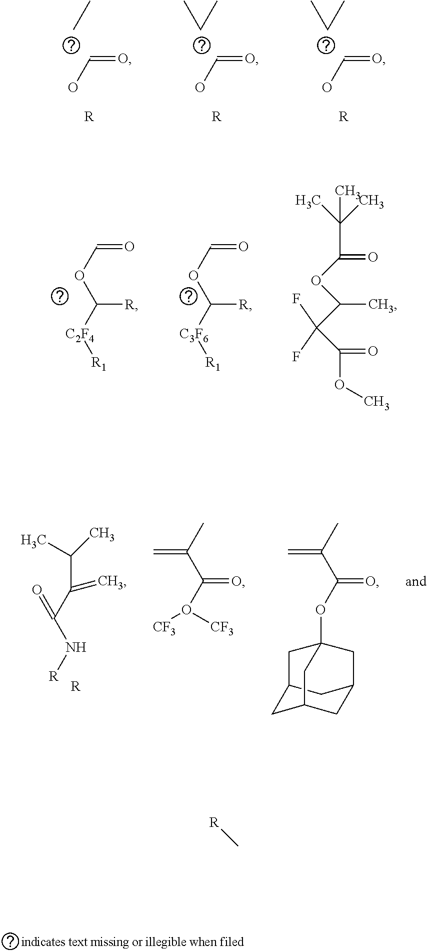

wherein R and R¹ are selected from unbranched or branched, cyclic, saturated, 1 to 30 carbon units with a hydrogen or halogen group, or —S—; —P—; —P(O₂)—; —C(═O)S—; —C(═O)O—; —O—; —N—; —C(═O)N—; —SO₂O—; —SO₂S—; —SO—, —SO₂—, a carboxylic acid group, an ether group, a ketone group, an ester group, or a phenyl group.

In another embodiment of the disclosure, a method of manufacturing a semiconductor device is provided. The method includes forming a target layer over a semiconductor substrate. The method includes disposing an underlayer over the target layer. The method includes forming a metallic photoresist layer over the underlayer. The method includes forming a floating additive layer over the metallic photoresist layer. The method includes selectively exposing the metallic photoresist layer to actinic radiation with an immersion photolithography apparatus to form exposed regions and unexposed regions in the metallic photoresist layer. In some embodiments, the actinic radiation passes through an immersion fluid disposed over the floating additive layer. The method includes developing the selectively exposed metallic photoresist layer to form a pattern in the metallic photoresist layer. The method includes transferring the pattern of the patterned metallic photoresist layer into the target layer.

In certain embodiments, the metallic photoresist layer is heated at a temperature ranging from 40 °C to 300 °C before selectively exposing the metallic photoresist layer to the actinic radiation. In some embodiments, the metallic photoresist layer is formed in a vacuum chamber. In some embodiments, the floating additive layer is formed by spin coating, chemical vapor deposition, plasma vapor deposition, or atomic layer deposition. In other embodiments, the metallic photoresist layer comprises a metal core including a metal selected from the group consisting of Sn, Sb, In, Cs, Ba, La, Ce, Ag, Zr, Zn, Hf, and Ti, wherein the metal is provided as a metal oxide or the metal is bound to a R linkage unit selected from a 1-9 carbon (C1-C9) unbranched, C3-C9 branched, C3-C9 cyclic or noncyclic, saturated or unsaturated, aromatic or non-aromatic, unsubstituted or halogen-substituted group; or —S—; —P—; —P(O₂)—; —C(═O)S—; —C(═O)O—; —O—; —N—; —C(═O)N—; —SO₂O—; —SO₂S—; —SO—; —SO₂—; a carboxylic acid group, an ether group, a ketone group, an ester group, or an aryl group.

In another embodiment of the disclosure, a method of forming a photoresist pattern is disclosed. The method includes introducing a metallic photoresist composition into a chamber for depositing a metallic photoresist layer over a substrate. The method includes applying a floating additive composition to the metallic photoresist layer while the metallic photoresist layer is forming on the substrate to form a mixture. The method includes rotating the substrate with the mixture disposed thereon. In some embodiments, the floating additive separates from the metallic photoresist rising to an upper portion of the mixture forming an upper layer comprising the floating additive disposed over the metallic photoresist layer. The method includes exposing the upper layer and the metallic photoresist layer to actinic radiation. The method includes developing the photoresist layer to form a pattern in the photoresist layer. The method includes removing the upper layer.

In other embodiments, the floating additive material is selected from the group consisting of:

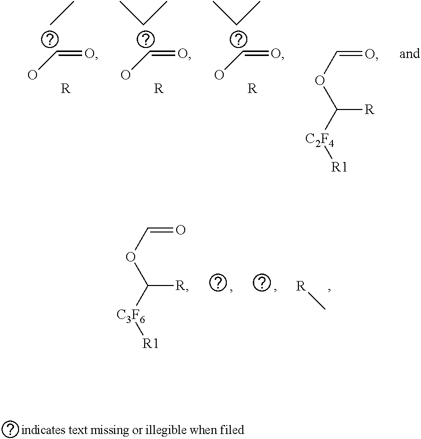

wherein R and R¹ are selected from unbranched or branched, cyclic, saturated, 1 to 30 carbon units with a hydrogen or halogen group, or —S—; —P—; —P(O₂)—; —C(═O)S—; —C(═O)O—; —O—; —N—; —C(═O)N—; —SO₂O—; —SO₂S—; —SO—, —SO₂—, a carboxylic acid group, an ether group, a ketone group, an ester group, or a phenyl group. In other embodiments, a thickness of the metallic photoresist layer and the upper layer ranges from 0.5 to 100 nm.

The foregoing outlines features of several embodiments or examples so that those skilled in the art may better understand the aspects of the present disclosure. Those skilled in the art should appreciate that they may readily use the pre modifying other processes and structures for carry same advantages of the embodiments or examples

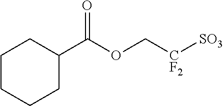

should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a metallic photoresist layer comprising a metallic photoresist composition over a substrate;
disposing a floating additive layer comprising a floating additive material;
selectively exposing the metallic photoresist layer to actinic radiation to form exposed regions and unexposed regions in the metallic photoresist layer, wherein the actinic radiation passes through an immersion fluid applied to a light projection device; and
developing the selectively exposed metallic photoresist layer to form a pattern in the metallic photoresist layer.

2. The method according to claim 1, wherein the metallic photoresist layer is formed in a vacuum chamber or ambient conditions.

3. The method according to claim 1, wherein the floating additive material is added to the metallic photoresist composition before forming the metallic photoresist layer.

4. The method according to claim 1, wherein the floating additive layer comprising the floating additive material is formed over the metallic photoresist layer before selectively exposing the metallic photoresist layer to the actinic radiation.

5. The method according to claim 1, further comprising forming an underlayer over the substrate before forming the metallic photoresist layer, wherein the underlayer comprises a bottom anti-reflective coating (BARC).

6. The method according to claim 1, wherein the metallic photoresist composition comprises a metallic core including a metal-oxo cage compound.

7. The method according to claim 6, wherein the metal-oxo cage compound comprises a tin-oxo core structure including carbon ligands and hydroxide counterions.

8. The method according to claim 1, wherein the metallic photoresist composition comprises a metallic core including an octahedral metal-oxo cluster.

9. The method according to claim 8, wherein the octahedral metal-oxo cluster comprises zirconium or titanium.

10. The method according to claim 1, wherein the floating additive layer is formed by spin coating, chemical vapor deposition, plasma vapor deposition, or atomic layer deposition.

11. The method according to claim 1, wherein a thickness of the metallic photoresist layer and the floating additive layer ranges from 0.5 to 100 nanometers (nm).

12. The method according to claim 1, wherein the floating additive material is selected from the group consisting of: 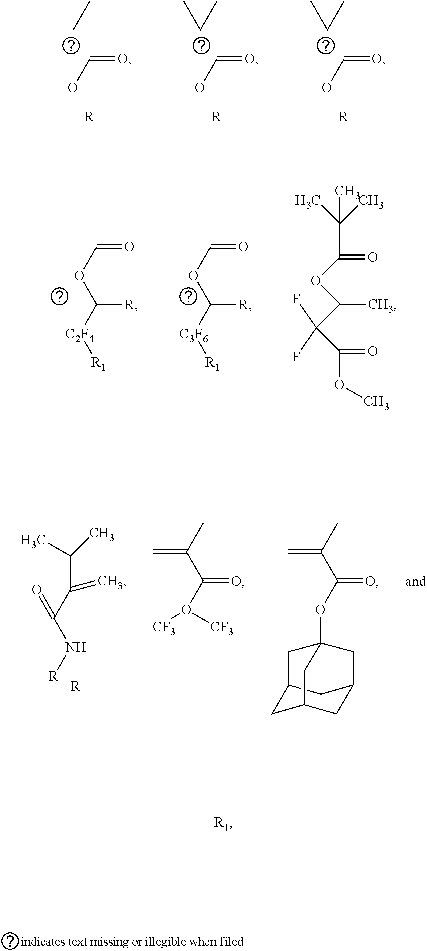
wherein R and R¹ are selected from unbranched or branched, cyclic, saturated, 1 to 30 carbon units with a hydrogen or halogen group, or —S—; —P—; —P(O₂)—; —C(═O)S—; —C(═O)O—; —O—; —N—; —C(═O)N—; —SO₂O—; —SO₂S—; —SO—, —SO₂—, a carboxylic acid group, an ether group, a ketone group, an ester group, or a phenyl group.

13. A method of manufacturing a semiconductor device, comprising:
forming a target layer over a semiconductor substrate; 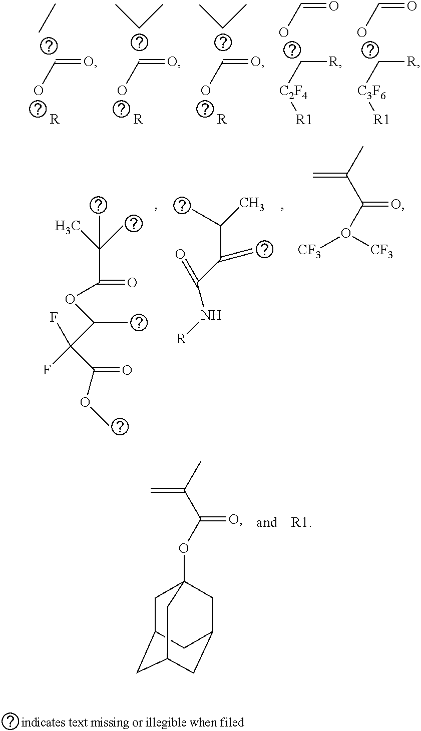
disposing an underlayer over the target layer;
forming a metallic photoresist layer over the underlayer;
forming a floating additive layer over the metallic photoresist layer;
selectively exposing the metallic photoresist layer to actinic radiation with an immersion photolithography apparatus to form exposed regions and unexposed regions in the metallic photoresist layer, wherein the actinic radiation passes through an immersion fluid disposed over the floating additive layer;
developing the selectively exposed metallic photoresist layer to form a pattern in the metallic photoresist layer; and
transferring the pattern of the patterned metallic photoresist layer into the target layer.

14. The method according to claim 13, further comprising heating the metallic photoresist layer at a temperature ranging from 40 °C to 300 °C before selectively exposing the metallic photoresist layer to the actinic radiation.

15. The method according to claim 13, wherein the metallic photoresist layer is formed in a vacuum chamber or ambient conditions.

16. The method according to claim 13, wherein the floating additive layer is formed by spin coating, chemical vapor deposition, plasma vapor deposition, or atomic layer deposition.

17. The method according to claim 13, wherein the metallic photoresist layer comprises a metal core including a metal selected from the group consisting of Sn, Sb, In, Cs, Ba, La, Ce, Ag, Zr, Zn, Hf, and Ti, wherein the metal is provided as a metal oxide or the metal is bound to a R linkage unit selected from a 1-9 carbon (C1-C9) unbranched, C3-C9 branched, C3-C9 cyclic or noncyclic, saturated or unsaturated, aromatic or non-aromatic, unsubstituted or halogen-substituted group; or —S—; —P—; —P(O₂)—; —C(═O)S—; —C(═O)O—; —O—; —N—; —C(═O)N—; —SO₂O—; —SO₂S—; —SO—; —SO₂—; a carboxylic acid group, an ether group, a ketone group, an ester group, or an aryl group.

18. A method of forming a photoresist pattern, comprising:
introducing a metallic photoresist composition into a chamber for depositing a metallic photoresist layer over a substrate;
applying a floating additive composition to the metallic photoresist layer while the metallic photoresist layer is forming on the substrate to form a mixture;
rotating the substrate with the mixture disposed thereon, wherein the floating additive composition separates from the metallic photoresist rising to an upper portion of the mixture forming an upper layer comprising the floating additive composition disposed over the metallic photoresist layer;
exposing the upper layer and the metallic photoresist layer to actinic radiation;
developing the photoresist layer to form a pattern in the photoresist layer; and
removing the upper layer.

19. The method of claim 18, wherein a thickness of the metallic photoresist layer and the upper layer ranges from 0.5 to 100 nanometers (nm).

20. The method of claim 18, wherein the floating additive composition is selected from the group consisting of: 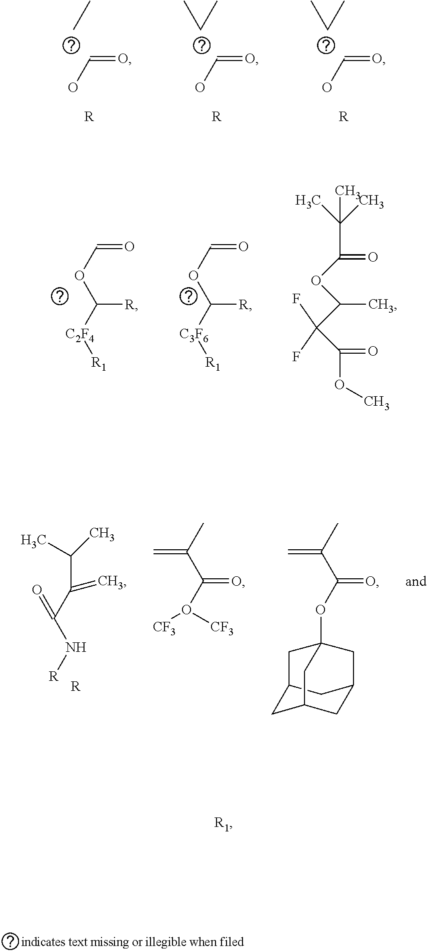
wherein R and R¹ are selected from unbranched or branched, cyclic, saturated, 1 to 30 carbon units with a hydrogen or halogen group, or —S—; —P—; —P(O₂)—; —C(═O)S—; —C(═O)O—; —O—; —N—; —C(═O)N—; —SO₂O—; —SO₂S—; —SO—, —SO₂—, a carboxylic acid group, an ether group, a ketone group, an ester group, or a phenyl group.
